(19) United States
(12) Patent Application Publication
(10) Pub. No.: US 2025/0338648 A1
(43) Pub. Date: Oct. 30, 2025

(54) ELECTRONIC DEVICE

(71) Applicant: STMicroelectronics International N.V., Geneva (CH)

(72) Inventor: Francois ROY, Seyssins (FR)

(73) Assignee: STMicroelectronics International N.V., Geneva (CH)

(21) Appl. No.: 19/178,138

(22) Filed: Apr. 14, 2025

(30) Foreign Application Priority Data
Apr. 16, 2024 (FR) FR2403909

(51) Int. Cl. H10F 39/00; H04N 25/709; H04N 25/771; H10F 39/18

(52) U.S. Cl. CPC H10F 39/80373; H04N 25/709; H04N 25/771; H10F 39/182

(57) ABSTRACT

An electronic device includes a pixel. The pixel includes: a photodiode; a charge transfer channel including first and second semiconductor regions where the second region is separated from the photodiode by the first region; and a trench surrounding the channel where the trench includes first and second conductive core and an insulating sheath. The first core laterally surrounds the first region and the second core laterally surrounds, at least partially, the second region. A control method for pixel selectively biases the first and second cores to set electrostatic potentials of the first and second semiconductor regions during pixel integration (substantially equal and at a high value), pixel charge transfer (respectively at different first and second low values) and two steps of passing from pixel charge transfer to pixel readout (first at high and second low values respectively and then at the same high value).

### PRIORITY CLAIM

This application claims the priority benefit of French Application for Patent No. FR2403909, filed on Apr. 16, 2024, the content of which is hereby incorporated by reference in its entirety to the maximum extent allowable by law.

### TECHNICAL FIELD

The present disclosure generally concerns electronic devices and, in particular, electronic devices comprising photodiodes.

### BACKGROUND

An electronic device, for example an image sensor, for example located in a digital device (digital camera, tablet, cell phone, etc.), comprises an assembly of photodetectors for capturing and converting the light of an exposure into electrical signals. In an image sensor of Complementary Metal Oxide Semiconductor (CMOS) type, the electrical signal of each individual photodetector is amplified and transmitted to an integrated circuit, to be processed at the same time. Afterwards, the photodetectors are erased to capture the next exposure.

In an image sensor which uses backside illumination (BSI), the light is exposed on a rear surface of the image sensor.

The sensor circuit which converts light into a digital signal is preferably arranged on the front surface, that is, the surface opposite to the rear surface, of the image sensor. An image sensor may use a photoelectric effect to absorb and convert light into an electron-hole pair at each of the photodetectors. In an image sensor, for example using photodiodes, charge carriers (that is, holes or electrons) are generated and stored in the depletion region of the photodiode during an integration period in the photodetector readout cycle. During a charge transfer period in the photodetector readout cycle, the charge carriers around the depletion region are transferred to a connection node and a corresponding digital representation of the level of exposed light at the photodetector is generated.

### SUMMARY

In an embodiment, an electronic device comprises a pixel, where the pixel comprises: a photodiode located in a substrate; a charge transfer channel comprising a first semiconductor region and a second semiconductor region, the second semiconductor region being separated from the photodiode by the first semiconductor region; and a trench surrounding the channel, the trench comprising a first conductive core, a second conductive core, and an insulating sheath, the first conductive core laterally surrounding the first semiconductor region and the second conductive core laterally surrounding at least partially the second semiconductor region, the first conductive core and the second conductive core being configured to be biased in such a way that: in an integration operation, electrostatic potentials of the first semiconductor region and the second semiconductor region are substantially equal and are at a high value; in a charge transfer operation, the electrostatic potentials of the first semiconductor region and the second semiconductor region are, respectively, at a first low value and a second low value, the first low value being higher than the second low value; in a first step of passage from the charge transfer operation to a readout operation, the electrostatic potential of the first semiconductor region is at the high value and the electrostatic potential of the second semiconductor region is at the second low value; and in a second step of passage from the charge transfer operation to the readout operation, the electrostatic potentials of the first semiconductor region and the second semiconductor region are substantially equal and are equal to the high value.

An embodiment provides a method of controlling an electronic device comprising a pixel, where the pixel comprises: a photodiode located in a substrate; a charge transfer channel comprising a first semiconductor region and a second semiconductor region, the second semiconductor region being separated from the photodiode by the first semiconductor region; and a trench surrounding the channel, the trench comprising a first conductive core, a second conductive core, and an insulating sheath, the first conductive core laterally surrounding the first semiconductor region and the second conductive core laterally surrounding at least partially the second semiconductor region, the method comprising: performing an integration during which the first conductive core and the second conductive core are biased in such a way that the electrostatic potentials of the first semiconductor region and of the second semiconductor region are substantially equal and are at a high value; performing a charge transfer during which the first conductive core and the second conductive core are biased in such a way that the electrostatic potentials of the first semiconductor region and of the second semiconductor region respectively are at a first low value and at a second low value, the first low value being higher than the second low value; performing a first step of passage from charge transfer to readout, during which the first conductive core and the second conductive core are biased in such a way that the electrostatic potential of the first semiconductor region is at the high value and the electrostatic potential of the second semiconductor region is at the second low value; and performing a second step of passage from charge transfer to readout, during which the first conductive core and the second conductive core are biased in such a way that the electrostatic potentials of the first semiconductor region and of the second semiconductor region are substantially equal and are equal to the high value.

According to an embodiment, the photodiode comprises third and fourth semiconductor regions in contact with each other and having opposite doping types, the fourth semiconductor region being in contact with the first semiconductor region.

According to an embodiment, the first semiconductor region and the second semiconductor region are doped with the same conductivity type.

According to an embodiment, the first semiconductor region and the second semiconductor region have a substantially equal dopant concentration.

According to an embodiment, the voltages applied to the first and second conductive cores are different at least during pixel operation.

According to an embodiment, the thickness of the sheath separating the first semiconductor region and the first conductive core is different from the thickness of the sheath separating the second semiconductor region and the second conductive core.

According to an embodiment, the first conductive core and second conductive core are separated by a portion of the sheath.

According to an embodiment, the first conductive core and the second conductive core are doped with the same conductivity type.

According to an embodiment, the first conductive core and the second conductive core are made of doped semiconductor materials of opposite types.

According to an embodiment, the second low value is substantially equal to the value of the electrostatic potential in an output node of the pixel.

According to an embodiment, the pixel is laterally surrounded by an insulated conductive wall.

According to an embodiment, the second conductive core entirely laterally surrounds the second semiconductor region.

According to an embodiment, the first conductive core comprises a first portion laterally surrounding the first semiconductor region and a second portion, the second conductive core located between the second semiconductor region and the second portion.

According to an embodiment, the first conductive core comprises a first portion laterally surrounding the first semiconductor region and a second portion, the second semiconductor region being laterally surrounded partially by the second conductive core and partially by the second portion.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, and FIG. 1C show, partially and schematically, an embodiment of a pixel of an electronic device;

FIG. 2A, FIG. 2B, FIG. 2C, and FIG. 2D illustrate the operation of the method of FIGS. 1A to 1C;

FIG. 3A and FIG. 3B show, partially and schematically, another embodiment of an image sensor pixel;

FIG. 4 shows, partially and schematically, another embodiment of an image sensor pixel;

FIGS. 5A and 5B show, partially and schematically, another embodiment of an image sensor pixel;

FIG. 6 shows a variant of the embodiment of FIGS. 5A and 5B; and

FIG. 7 shows another variant of the embodiment of FIGS. 5A and 5B.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In order to allow a better charge retention in the storage region of the pixel, that is, the drain region of the pixel, the pixel comprises two successive transfer gates. The two gates are configured so that, during the pixel integration period, the electrostatic potential at the two gates is identical to a first value. The two gates are also configured so that, during the charge transfer period, the electrostatic potential at the gate closest to the charge storage region of the pixel is higher than that of the other gate. At the end of the charge transfer period, the gates are configured so that the electrostatic potential of the gate closest to the charge storage region of the pixel returns to the first value before that of the other gate.

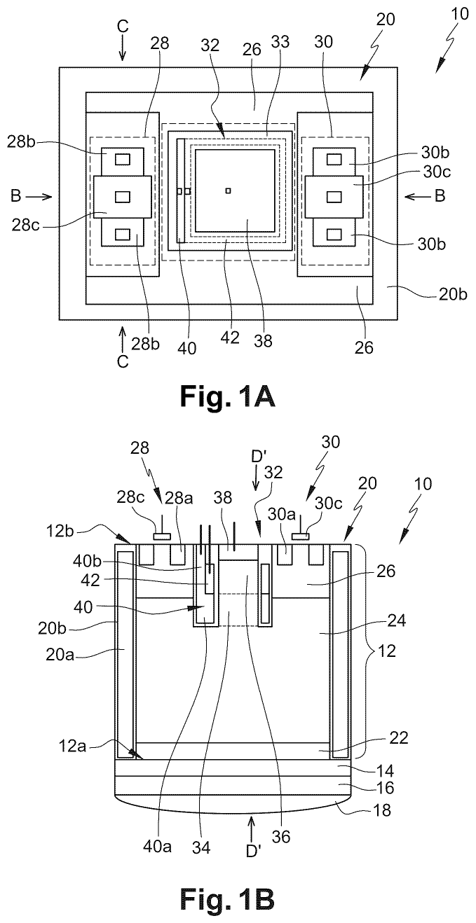

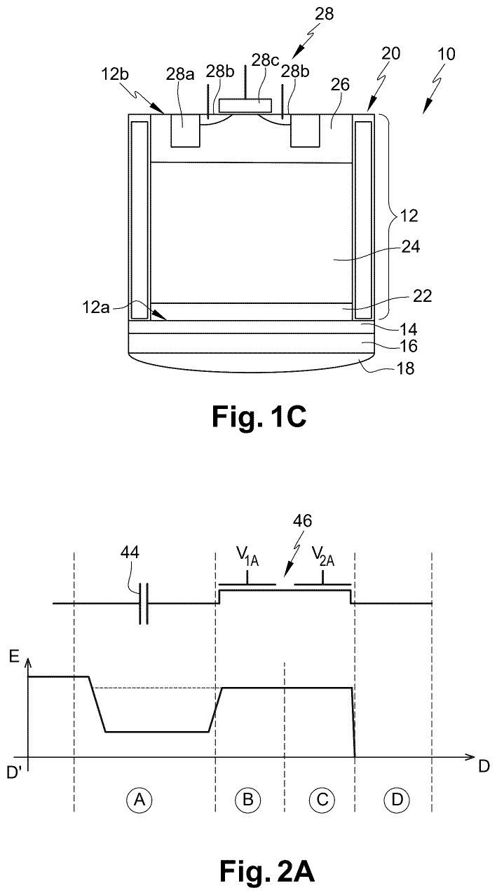

FIG. 1A, FIG. 1B, and FIG. 1C show, partially and schematically, an embodiment of a pixel 10c. More specifically, FIG. 1A shows a top view of the pixel of FIGS. 1B and 1C. FIG. 1B shows a cross-section view of the pixel of FIG. 1A along a plane B-B of FIG. 1A. FIG. 1C shows a cross-section view of the pixel of FIG. 1A along a plane C-C of FIG. 1A.

The image sensor comprises a plurality of pixels 10, arranged in an array, that is, in rows and in columns. Each pixel 10 comprises at least one photodetector, for example a photodiode. In the example of FIGS. 1A to 1C, pixel 10 comprises a single photodiode.

Pixel 10 is formed in a substrate 12. Substrate 12 is, for example, a semiconductor substrate, for example made of silicon. Substrate 12 comprises a first surface 12a, referred to as the rear surface, and a second surface 12b, referred to as the front surface.

The pixel 10 of FIGS. 1A to 1C is a backside-illuminated pixel. In other words, the pixel is configured so that the photodiode receives light rays at its rear surface, the charges then being extracted from the opposite surface, the front surface. Thus, the rear surface 12a of substrate 12 is covered, at least at the location of the pixel, with optical elements.

The rear surface of the substrate is, for example, covered with one or a plurality of layers 14. In the example of FIGS. 1A to 1C, the pixel comprises a single layer 14. Layer 14 is, for example, a layer having anti-reflective and/or passivation properties. Layer 14 directly covers, for example, surface 12a.

The pixel comprises, for example, one or a plurality of layers 16. In the example of FIGS. 1A to 1C, the pixel comprises a single layer 16. Layer 16 is, for example, a filter. Layer 16 is, for example, configured to filter one or a plurality of wavelengths. Layer 16 covers, for example, layer 14, with layer 14 being located between layer 16 and substrate 12.

Further, the pixel comprises, for example, a lens 18, for example configured to focus light rays into the photodiode. Lens 18 covers, for example, layer 16, with layer 16 being located between layer 14 and the lens.

The pixel is surrounded by a wall 20. Wall 20 is preferably an insulating wall, for example a conductive insulating wall. More specifically, wall 20 preferably comprises a conductive core 20a and an insulating sheath 20b. The conductive core 20a of wall 20 is, for example, configured to be biased in such a way as to deplete the photodiode. Wall 20 preferably extends along at least the height of the pixel photodiode, preferably along the entire height of substrate 12.

The photodiode of the pixel comprises regions 22, 24, and 26 of the substrate. Regions 22 and 24 are doped with opposite doping types. Similarly, regions 24 and 26 are doped with opposite doping types. For example, region 22 is N-type doped, region 24 is P-type doped, and region 26 is N-type doped. Regions 22 and 24 are preferably in contact in such a way as to form a PN junction. Regions 24 and 26 are preferably in contact in such a way as to form a PN junction.

Region 22 is located at the rear surface of substrate 12. More precisely, region 22 is flush with surface 12a. Thus, a surface of region 22 is coplanar with surface 12a.

Region 24 is located in substrate 12. Thus, region 24 is separated from surface 12a by region 22.

Region 26 is located at the front surface of substrate 12. More precisely, region 26 is flush with surface 12b. Thus, a surface of region 26 is coplanar with surface 12b. Region 26 forms a ring extending in the periphery of the pixel. More specifically, region 26 extends along the sides of wall 20. Region 26 is thus separated from region 22 by region 24.

Regions 22, 24, and 26 are surrounded by wall 20. Preferably, regions 22, 24, and 26 are in lateral contact with wall 20. Thus, regions 22 and 24 are preferably not separated from the wall by other semiconductor regions.

Region 26 comprises one or a plurality of transistors, for example one or a plurality of metal oxide semiconductor field-effect transistors (MOSFETs). In the example of FIGS. 1A to 1C, region 26 comprises two MOSFET transistors 28 and 30.

Each transistor 28, 30 is located in a portion of region 26 surrounded by an insulating wall, respectively 28a, 30a. Walls 28a, 30a are, for example, of shallow trench insulation (STI) type. Walls 28a, 30a preferably extend along a height smaller than the height of region 26. Walls 28a, 30a preferably extend from front surface 12b. Thus, walls 28a and 30a preferably only extend in region 26.

Transistor 28, respectively 30, comprises in the portion of region 26 surrounded by wall 28a, source and drain regions 28b, respectively 30b. Transistor 28 further comprises a gate 28c, respectively 30c, schematically shown in FIGS. 1A to 1C.

The pixel further comprises a trench 32. Trench 32 comprises one or a plurality of conductive cores 40, 42 and an insulating sheath 33. The trench extends in substrate 12 from the front side of substrate 12. Trench 32 extends along the inner sidewalls of the ring formed by region 26. Thus, region 26 is laterally defined by wall 20 and trench 32. Trench 32 has a height preferably at least equal to the height of region 26, preferably greater than the height of region 26.

The trench 32 forms a ring around a portion of substrate 12. More specifically, trench 32 forms a ring around regions 34, 36, 38 of substrate 12. Regions 34, 36, 38 form a charge transfer channel. Regions 34, 36, 38 are preferably entirely laterally surrounded by trench 32. Regions 34, 36, 38 are preferably made of a semiconductor material, preferably of the material of the substrate. Regions 34 and 36 are preferably made of the same material. Regions 34 and 36 are preferably doped with the same dopant. Regions 34, 36, 38 are preferably doped with the same conductivity type, preferably with the conductivity type of region 24. In the example of FIGS. 1A to 1C, regions 34, 36, 38 are, for example, P-doped. The dopant concentration in regions 34 and 36 is, for example, substantially identical. Region 34 is in contact with the front surface of region 24. Region 36 is in contact with the front surface of region 34. Region 36 is thus separated from region 24 by region 34. Region 38 is in contact with the front surface of region 36. Region 38 is thus separated from region 34 by region 36. For example, region 38 is flush with the front surface 12b of substrate 12.

In the example of FIGS. 1A to 1C, trench 32 comprises two conductive cores 40 and 42. Trench 32 thus corresponds to a double transfer gate, and the charges generated in the photodiode can be extracted via regions 34, 36, 38 by the control of the transfer gates.

Conductive cores 40 and 42 are, for example, made of a same material, for example of a semiconductor material. Conductive cores 40 and 42 are, for example, made of polysilicon. Alternatively, cores 40 and 42 may be made of different materials. Preferably, cores 40 and 42 are doped with opposite types. For example, core 42 is of the same conductivity type as region 24, for example, type P. For example, core 42 is of the same conductivity type as region 36. For example, core 40 is of the same conductivity type as region 22, for example type N. For example, core 40 is of the conductivity type opposite to that of region 34. Sheath 33 is, for example, made of a silicon oxide, for example a nitrided silicon oxide. The dopant concentration in cores 40 and 42 is preferably different. For example, the dopant concentration in core 40 is higher than the dopant concentration in core 42.

Conductive core 40 comprises a lower portion 40a and an upper portion 40b. Portion 40a forms a ring laterally surrounding region 34. The height of portion 40a is preferably substantially equal to the height of region 34. Preferably, the upper surface of portion 40 is substantially coplanar with the upper surface of region 34.

Portion 40a is configured to be biased by a control circuit for the pixel with a first control voltage, for example via upper portion 40b. Upper portion 40b is in contact with lower portion 40a. Upper portion 40b extends, for example, from lower portion 40a to the front surface of substrate 12. Thus, core 40 may be biased from the front surface of substrate 12.

Conductive core 42 is located above core 40. In other words, core 42 is located between core 40 and front surface 12b. Core 42 laterally surrounds at least a portion of region 36, preferably a lower portion of region 36. Core 42 is, for example, in contact with the upper surface of portion 40a and is, for example, in contact with a sidewall of portion 40b. Portion 40b is separated from region 36 by core 42. Core 42 is configured to be biased by the control circuit for the pixel with a second control voltage, preferably from the front surface of the substrate.

Preferably, the thickness of sheath 33 is constant. In other words, region 34 and portion 40a are preferably separated by a thickness of sheath 33 substantially equal to the thickness of sheath 33 separating core 42 and region 36.

The first control voltage and the second control voltage are preferably independent of each other and generated by the pixel control circuitry.

Cores 40 and 42 are separated from regions 24, 26, 34, 36, 38 by the insulating sheath 33 of trench 32. The insulating sheath and the conductive cores form the transfer gates.

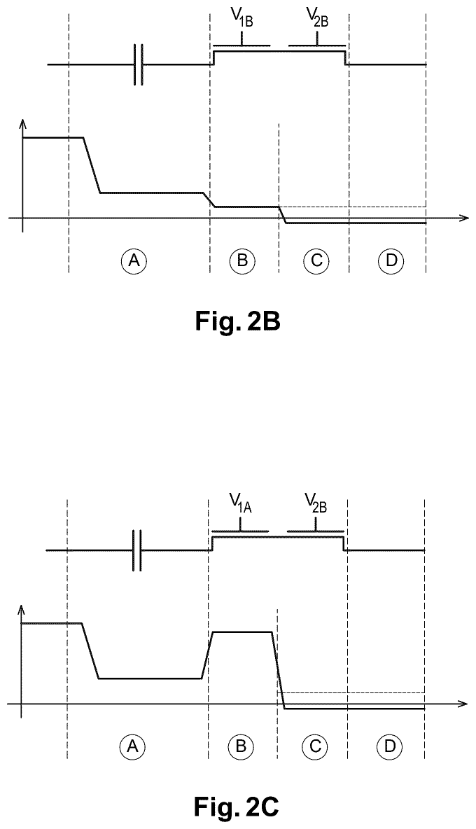

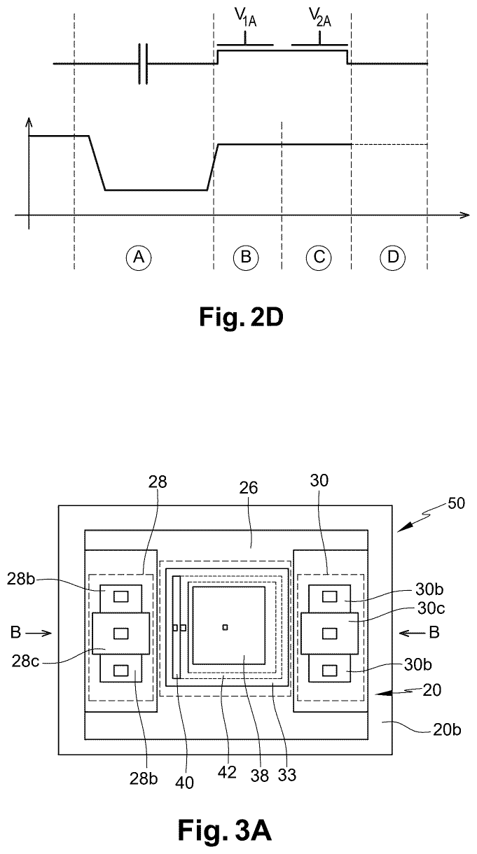

FIG. 2A, FIG. 2B, FIG. 2C, and FIG. 2D illustrate the operation of the embodiment of FIGS. 1A to 1C. More specifically, FIGS. 2A to 2D show charge diagrams for the electrostatic potential (E) along plane D-D′. FIGS. 2A to 2D thus comprise several areas A, B, C, D.

Area A corresponds to region 24. Area A is illustrated by a capacitor 44. Area A corresponds to the charge storage area.

Areas B and C correspond to the charge transfer transistor, and more precisely to the double charge transfer gates. Thus, areas B and C are illustrated by a transistor 46 comprising two gates. Area B corresponds to the first gate, implemented by core 40 and sheath 33. Area C corresponds to the second gate, implemented by core 42 and sheath 33.

Area D corresponds to the output node of the pixel, that is, the node coupled, preferably connected, to region 38.

FIG. 2A shows a photodiode integration operating phase or step. In other words, during the step of FIG. 2A, light rays reach the photodiode from the rear surface, and charges are generated in region 24.

During this operating step, region 24 is initially fully depleted, for example by the application by the control circuit of an adapted voltage, for example a positive voltage, to the core 20a of wall 20. Thus, the electrostatic potential in region 24 is lower than the electrostatic potential in region 22, the electrostatic potential in region 26, and the electrostatic potential in region 34. This forms a barrier against charge movement between regions 22 and 24, 26 and 24, and 34 and 24.

The first voltage and the second voltage, respectively applied to the first transfer gate and to the second transfer gate, that is, respectively to cores 40 and 42, by the pixel control circuitry are respectively equal to values V1A and V2A. Values V1A and V2A are, for example, different from each other. Values V1A and V2A are such that the electrostatic potentials in regions 34 and 36, that is, in areas B and C of FIG. 2A, are substantially equal to each other and are higher than the electrostatic potential in region 24. A barrier against charge movement is thus formed between region 34 and region 24. In other words, the transfer transistors are non-conducting.

Further, the electrostatic potential at the output node, that is, in area D, is lower than the electrostatic potentials of regions 24, 34, 36, for example the voltage is equal to zero.

The charges generated in region 24 by the reception of light rays are thus stored in region 24. The quantity of charges that can be stored in region 24 is represented by a dotted line and depends on the electrical potential difference between region 24 and region 34. The dotted line illustrates the value of the electrostatic potential, which increases with the quantity of charges stored in region 24 (the solid line symbolizes the electrostatic potential when the area is fully depleted, and the dotted line symbolizes the electrostatic potential in the presence of charges stored in region 24).

FIG. 2B shows a charge transfer operating phase or step. During this operating step, at least part of, preferably all, the charges stored in region 24 are transferred to the output node. In the case of a total transfer, the electrostatic potential of region 24 returns to its fully depleted area value (symbolized by a solid line).

During this operating step, the electrostatic potential of region 24 returns to its fully depleted area value (solid line), which corresponds to the initial or reset value of region 24.

During this operating step, the first voltage and the second voltage, respectively applied to the first transfer gate and to the second transfer gate, that is, respectively to cores 40 and 42, by the pixel control circuitry are respectively equal to values V1B and V2B. Values V1B and V2B are, for example, different from each other. Values V1B and V2B are, for example, respectively lower than values V1A and V1B. Values V1B and V2B are such that the electrostatic potential in region 34, corresponding to area B, is lower than the electrostatic potential of depleted region 24, and that the electrostatic potential in region 36, corresponding to area C, is lower than the electrostatic potential of region 34. Preferably, the value V2B of the second voltage is such that the electrostatic potential of region 36 is substantially equal to the electrostatic potential of the output node. In other words, the charge transfer transistors are conducting.

The barrier between region 24 and the output node is thus removed. The charges of region 24 are thus attracted to region 36 and the output node. The electrostatic potential corresponding to the quantity of transferred charges is represented by a dotted line in area D.

FIG. 2C shows a first operating phase or step of passage from the charge transfer operating step to an operating phase or step during which the transferred charges are read out and converted into an output voltage, corresponding for example to the integration operating step.

During this first operating step, the first voltage takes value V1A and the second voltage keeps value V2B. Thus, the charge transfer transistor comprising the first gate is non-conducting and the charge transfer transistor comprising the second gate is conducting. The voltages and control signals are generated by the pixel control circuitry.

The barrier preventing the charge transfer from region 24 is thus present again. The charges which have been transferred are kept in region 36 and in the output node.

FIG. 2D shows a second operating phase or step of passage from the charge transfer operating step to the operating step during which the transferred charges are read out and converted into an output voltage. The steps of FIGS. 2C and 2D are preferably successive.

During this second operating step, the second voltage takes value V2A and the first voltage keeps value V1A under the control of the pixel control circuitry. Thus, all the charges located in region 36 during the previous step are transferred into the output node, and the barrier preventing charges from returning to region 24 is present again.

The limit of charges capable of being stored in the output node is determined by the electrostatic potential in region 36 and is represented by a dotted line in area D.

The image sensor, with the pixels 10, includes pixel control circuitry (not explicitly shown) which is configured to control operation through the various operating phases or steps, and in particular to properly generate the first and second voltages at the necessary voltage values as described above. As previously noted, the first control voltage and the second control voltage are preferably independent of each other, with the voltages being generated by the control circuitry dependent on operating phase or step.

It could have been chosen to form a single transfer gate surrounding regions 34 and 36 and receiving a single voltage, regions 34 and 36 having different dopant concentrations. Said dopant concentrations could have been selected so that the electrostatic potential in region 36 is lower than the electrostatic potential in region 34. However, the quantity of charges capable of being stored in the output node would have been lower.

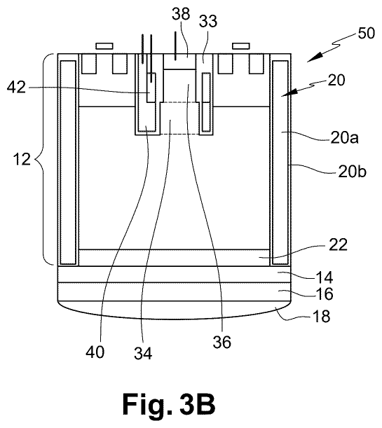

FIG. 3A and FIG. 3B show, partially and schematically, another embodiment of a pixel 50 of an electronic device, for example an image sensor. More specifically, FIG. 3A shows a top view of the pixel 50 of FIG. 3B. FIG. 3B shows a cross-section view of the pixel of FIG. 3A along a plane B-B of FIG. 3A.

Pixel 50 comprises the elements of pixel 10. These elements are designated with the same references and will not be described again in detail.

Pixel 50 differs from the pixel 10 of FIGS. 1A to 1C in that the thickness of sheath 33 separating core 42 from region 36 is different from the thickness of sheath 33 separating core 40 from region 34. Preferably, the difference between the sheath thicknesses is at least 20%. In the example of FIGS. 3A and 3B, the thickness of sheath 33 separating core 42 from region 36 is greater than the thickness of sheath 33 separating core 40 from region 34.

According to an embodiment, the doping concentrations of cores 40 and 42 are substantially identical. According to an embodiment, values V1A and V2A generated by the pixel control circuitry are such that the electrostatic potential of regions 34 and 36 are substantially equal during the integration steps. Values V1B and V2B are, for example, substantially identical, the electrostatic potential difference during the transfer step being generated by the thickness difference of sheath 33 at regions 34 and 36.

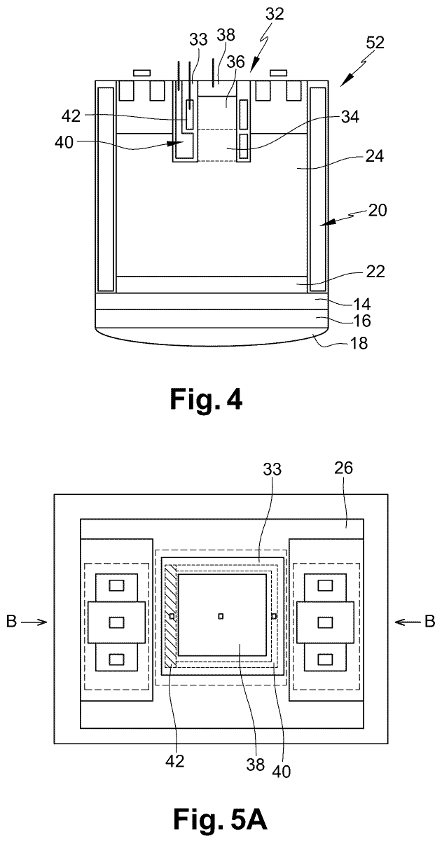

FIG. 4 shows, partially and schematically, another embodiment of a pixel 52 of an electronic device, for example an image sensor. More specifically, FIG. 4 shows a cross-section view of pixel 52 along a plane B-B similar to the plane B-B of FIG. 2A.

Pixel 52 comprises the elements of pixel 10. These elements are designated with the same references and will not be described again in detail.

Pixel 52 differs from the pixel 10 of FIGS. 1A to 1C in that cores 40 and 42 are separated from each other by a portion of sheath 33. Thus, insulating sheath 33 extends around each core 40 and 42. Cores 40 and 42 are thus not in contact.

According to the embodiment of FIG. 4, cores 40 and 42 may be of different doping types, as in the embodiment of FIGS. 1A to 1C, or of identical doping types.

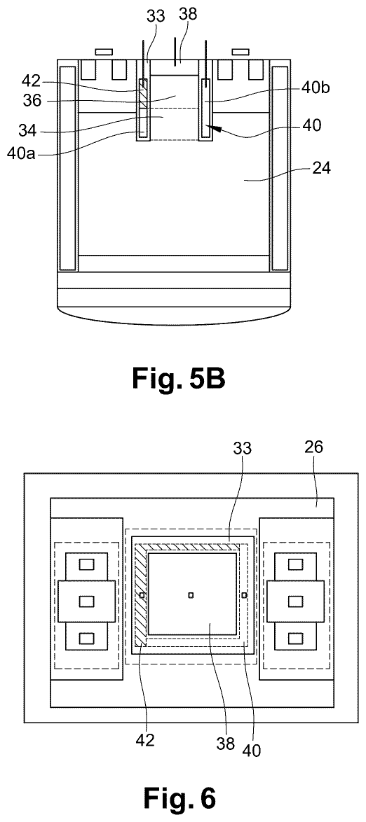

FIGS. 5A and 5B show, partially and schematically, another embodiment of a pixel 54 of an electronic device, for example an image sensor. More specifically, FIG. 5A shows a top view of the pixel 54 of FIG. 5B. FIG. 5B shows a cross-section view of the pixel 54 of FIG. 5A along a plane B-B of FIG. 5A.

Pixel 54 comprises the elements of pixel 10. These elements are designated with the same references and will not be described again in detail.

Pixel 50 differs from the pixel 10 of FIGS. 1A to 1C in that core 42, hatched in FIG. 5A, only extends over a portion of the contour of region 36. More specifically, in the embodiment of FIGS. 5A and 5B, core 42 extends along a side of the rectangular contour surrounding region 36.

Core 42 is in vertical alignment with portion 40a of core 40. Thus, core 42 is not separated from region 36 by core 40. Similarly, core 40, and in particular portion 40b, is not separated from regions 34 and 36 by core 42.

Region 34 is laterally surrounded by portion 40a of core 40. Region 34 is preferably not surrounded, even partially, by core 42. Region 36 is surrounded by a contour comprising, on one side, core 42, and on the other sides, for example the three other sides, portion 40b of core 40.

In the embodiment of FIGS. 5A and 5B, cores 40 and 42 are preferably, as in the embodiment shown in FIGS. 1A to 1C, doped with opposite conductivity types. The operation of the embodiment of FIGS. 5A and 5B is identical to the operation of the embodiment of FIGS. 1A to 1C, described in relation with FIGS. 2A to 2D.

FIG. 6 shows a variant of the embodiment of FIGS. 5A and 5B.

The embodiment of FIG. 6 differs from the embodiment of FIGS. 5A and 5B in that core 42, hatched in FIG. 5A, extends on two sides of the rectangular contour surrounding region 36.

As in FIGS. 5A and 5B, core 42 is in vertical alignment with portion 40a of core 40. Thus, core 42 is not separated from region 36 by core 40. Similarly, core 40, and in particular portion 40b, is not separated from regions 34 and 36 by core 42.

Region 34 is laterally surrounded by portion 40a of core 40. Region 34 is preferably not surrounded, even partially, by core 42. Region 36 is surrounded by a contour comprising, on two sides, core 42, and on the other sides, for example the two other sides, portion 40b of core 40.

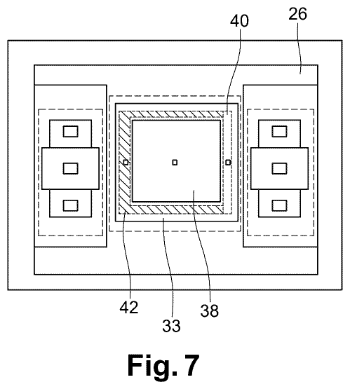

FIG. 7 shows another variant of the embodiment of FIGS. 5A and 5B.

The embodiment of FIG. 7 differs from the embodiment of FIGS. 5A and 5B in that core 42, hatched in FIG. 5A, extends on three sides of the rectangular contour surrounding region 36.

Core 42 is, as in FIGS. 5A and 5B, in vertical alignment with portion 40a of core 40. Thus, core 42 is not separated from region 36 by core 40. Similarly, core 40, and in particular portion 40b, is not separated from regions 34 and 36 by core 42.

Region 34 is laterally surrounded by portion 40a of core 40. Region 34 is preferably not surrounded, even partially, by core 42. Region 36 is surrounded by a contour comprising, on three sides, core 42, and on the other sides, for example the only other side, portion 40b of core 40.

An advantage of the described embodiments is that they enable to ensure that the charges transferred to the output node cannot return into the storage region of the photodiode.

Various embodiments and variants have been described. Those skilled in the art will understand that certain features of these various embodiments and variants may be combined, and other variants will occur to those skilled in the art. In particular, the doping types may be reversed with respect to the examples described in relation with the drawings. In the embodiment of FIGS. 3A and 3B, the thickness of sheath 33 separating core 42 from region 36 is smaller than the thickness of sheath 33 separating core 40 from region 34.

Finally, the practical implementation of the described embodiments and variants is within the abilities of those skilled in the art based on the functional indications given hereabove.

1. An electronic device, comprising:
a pixel including:
a photodiode located in a substrate;
a charge transfer channel comprising a first semiconductor region and a second semiconductor region, the second semiconductor region being separated from the photodiode by the first semiconductor region; and
a trench surrounding the channel, the trench comprising a first conductive core, a second conductive core and an insulating sheath which separates the first and second conductive cores from the first and second semiconductor regions, the first conductive core laterally surrounding the first semiconductor region and the second conductive core laterally surrounding at least partially the second semiconductor region.

2. The device according to claim 1, further comprising control circuit for generating control voltages for biasing the first conductive core and the second conductive core.

3. The electronic device according to claim 2, wherein the control circuit is configured to:
bias the first conductive core and the second conductive core during a pixel integration operation so that electrostatic potentials of the first semiconductor region and the second semiconductor region are substantially equal and are at a high value;
bias the first conductive core and the second conductive core during a pixel charge transfer operation so that the electrostatic potentials of the first semiconductor region and the second semiconductor region are, respectively, at a first low value and at a second low value, the first low value being higher than the second low value;
bias the first conductive core and the second conductive core during a first step of passage from the pixel charge transfer operation to a pixel readout operation so that the electrostatic potential of the first semiconductor region is at the high value and the electrostatic potential of the second semiconductor region is at the second low value; and
bias the first conductive core and the second conductive core during a second step of passage from the pixel charge transfer operation to the pixel readout operation so that the electrostatic potentials of the first semiconductor region and the second semiconductor region are substantially equal and are equal to the high value.

4. The device according to claim 3, wherein control voltages applied to the first conductive core and the second conductive core by the control circuit for biasing are different at least during a pixel operation.

5. The device according to claim 3, wherein the second low value is substantially equal to a value of electrostatic potential in an output node of the pixel.

6. The device according to claim 1, wherein the photodiode comprises a third semiconductor region and a fourth semiconductor region that are in contact with each other and have opposite doping types, the fourth semiconductor region being in contact with the first semiconductor region.

7. The device according to claim 1, wherein the first semiconductor region and the second semiconductor region are doped with the same conductivity type.

8. The device according to claim 1, wherein the first semiconductor region and the second semiconductor region have a substantially equal dopant concentration.

9. The device according to claim 1, wherein a thickness of the sheath separating the first semiconductor region and the first conductive core is different from a thickness of the sheath separating the second semiconductor region and the second conductive core.

10. The device according to claim 1, wherein the first conductive core and the second conductive core are separated by a portion of the sheath.

11. The device according to claim 10, wherein the first conductive core and the second conductive core are doped with the same conductivity type.

12. The device according to claim 1, wherein the first conductive core and the second conductive core are made of doped semiconductor materials of opposite types.

13. The device according to claim 1, wherein the pixel is laterally surrounded by an insulated conductive wall.

14. The device according to claim 1, wherein the second conductive core entirely laterally surrounds the second semiconductor region.

15. The device according to claim 14, wherein the first conductive core comprises a first portion laterally surrounding the first semiconductor region and a second portion, the second conductive core being located between the second semiconductor region and the second portion.

16. The device according to claim 1, wherein the first conductive core comprises a first portion laterally surrounding the first semiconductor region and a second portion, the second semiconductor region being laterally surrounded partially by the second conductive core and partially by the second portion.

17. A method of controlling an electronic device comprising a pixel, where the pixel comprises: a photodiode located in a substrate; a charge transfer channel comprising a first semiconductor region and a second semiconductor region, the second semiconductor region being separated from the photodiode by the first semiconductor region; and a trench surrounding the channel, the trench comprising a first conductive core, a second conductive core, and an insulating sheath, the first conductive core laterally surrounding the first semiconductor region and the second conductive core laterally surrounding at least partially the second semiconductor region, the method comprising:
biasing the first conductive core and the second conductive core during pixel integration such that the electrostatic potentials of the first semiconductor region and the second semiconductor region are substantially equal and are at a high value;
biasing the first conductive core and the second conductive core during pixel charge transfer such that the electrostatic potentials of the first semiconductor region and the second semiconductor region, respectively, are at a first low value and at a second low value, the first low value being higher than the second low value;
biasing the first conductive core and the second conductive core during a first step of passing from pixel charge transfer to pixel readout such that the electrostatic potential of the first semiconductor region is at the high value and the electrostatic potential of the second semiconductor region is at the second low value; and
biasing the first conductive core and the second conductive core during a second step of passing from pixel charge transfer to pixel readout such that the electrostatic potentials of the first semiconductor region and the second semiconductor region are substantially equal and are equal to the high value.

18. The method according to claim 17, comprising applying voltages to the first conductive core and to the second conductive core that are different at least during pixel operation.

19. The method according to claim 17, wherein the second low value is substantially equal to the value of the electrostatic potential in an output node of the pixel.
